(19) United States
(12) Patent Application Publication
(10) Pub. No.: US 2020/0145056 A1
(43) Pub. Date: May 7, 2020

(54) ARBITRARY SURFACE NEAR-FIELD ANTENNA TEST SYSTEM

(71) Applicant: NSI-MI Technologies, LLC, Suwanee, GA (US)

(72) Inventors: Daniel JANSE VAN RENSBURG, Cumming, GA (US); Brett WALKENHORST, Marietta, GA (US); Quang TON, Costa Mesa, CA (US)

(73) Assignee: NSI-MI Technologies, LLC, Suwanee, GA (US)

(21) Appl. No.: 16/671,743

(22) Filed: Nov. 1, 2019

Related U.S. Application Data
(60) Provisional application No. 62/755,161, filed on Nov. 2, 2018.

(51) Int. Cl. H04B 5/00; G01R 29/10; G01R 29/08

(52) U.S. Cl. CPC H04B 5/0043; G01R 29/0878; G01R 29/105

(57) ABSTRACT

A robotic near-field antenna measurement system allows for acquisition of near-field measurements on a non-canonical measurement surface. This near-field test data is transformed to a set of equivalent currents representing an antenna under test (AUT). These currents (if the equivalent surface is selected appropriately) allow for AUT diagnostics and calculation of all radiated fields. This test system provides a degree of flexibility that is not possible with conventional (canonical) near-field antenna test systems.

### CROSS-REFERENCE TO RELATED APPLICATIONS

The present application claims the benefit of U.S. Provisional Application No. 62/755,161, filed Nov. 2, 2018, under 35 U.S.C. § 119(e). The entire contents of that provisional application are incorporated herein by reference in their entirety.

### FIELD OF THE INVENTION

The present invention relates to the field of electromagnetic metrology and antenna testing.

### BACKGROUND OF THE INVENTION

Near-field antenna testing is a common technique, widely used in industry. Near-field measurements are taken, at an appropriate distance from the antenna under test (AUT), to acquire near-field values. One or more exemplary approaches may be found, for example, in C. G. Parini, S. F. Gregson, J. McCormick, D. Janse van Rensburg, “Theory and Practice of Modern Antenna Range Measurements”, Institute of Engineering and Technology Press, London, U K, 2015, ISBN 978-1-84919-560-7.

Known techniques have been restricted in that motion of an electromagnetic near-field probe during testing has had to be restricted to a measurement surface that is planar, cylindrical, or spherical. Such surfaces are examples of what have been termed canonical surfaces.

### SUMMARY OF THE INVENTION

New mathematical processing techniques enable arbitrary or non-canonical measurement surfaces. Aspects of the present invention relate to implementation of a near-field test technique that creates such an arbitrary surface, allowing for more versatility and space efficiency.

### BRIEF DESCRIPTION OF THE DRAWINGS

In the accompanying drawings:

FIG. 1 depicts the generation of a generatrix, which is contained within the x-z plane.

FIG. 2 depicts a multi-axis robot and a test stand for plotting points around an antenna under test (AUT).

FIG. 3 depicts another view of the multi-axis robot and test stand, showing plotting of additional points around the AUT.

FIG. 4 depicts an embodiment in which the robot is mounted on a translational apparatus.

FIG. 5 depicts a plurality of sample points for a near-field (NF) pillbox measurement surface using the apparatus of FIGS. 2-4.

FIG. 6 depicts a plurality of sample points for an NF pillbox measurement surface with a different technique, using the apparatus of FIGS. 2-4.

FIG. 7 depicts a plurality of sample points for an NF conically-shaped measurement surface using a technique according to an embodiment.

FIG. 8 depicts a plurality of sample points for an NF oblate spheroidal shaped measurement surface according to an embodiment.

FIG. 9 depicts a graphical representation of electric field amplitude of acquired field samples.

FIG. 10 depicts an example of a discretized AUT bounding surface according to an embodiment.

FIG. 11 depicts a high level schematic view of a computer-controlled robotic test system in accordance with an embodiment.

FIGS. 12A and 12B are flow charts setting out steps in performing antenna testing according to embodiments.

### DESCRIPTION OF EMBODIMENTS

The near-field antenna test system described herein relies on sampling electromagnetic field values on an arbitrary surface, enclosing an AUT. The enclosing measurement surface can take different forms, according to different embodiments. One such form results from a surface of revolution which is generated by defining a generatrix, comprised of a plurality of points, at a plurality of locations around the AUT. Another such form results from a spiral scan, as will be discussed in more detail below.

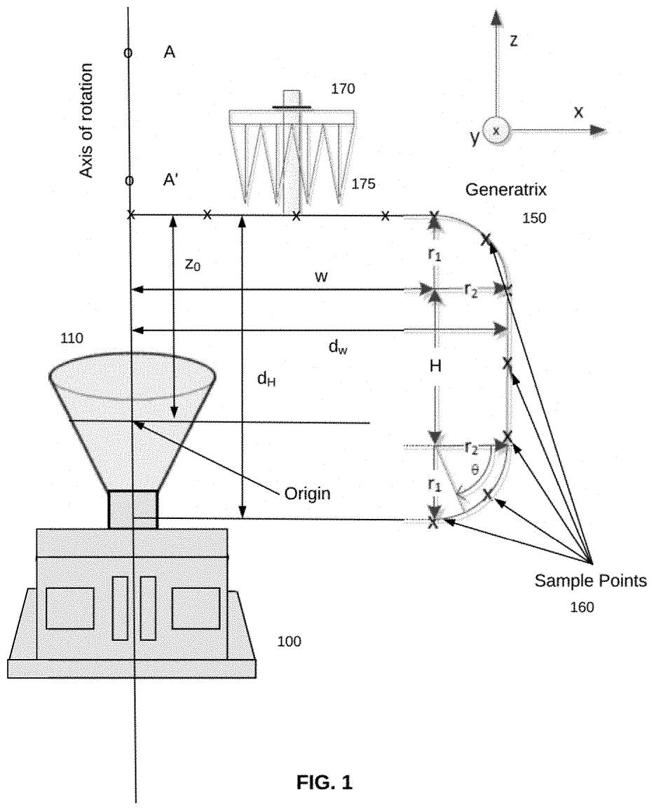

As will be discussed in more detail below, according to embodiments a multi-axis robot, with an electromagnetic near-field probe mounted on the robot's arm, generates a plurality of locations in a plane. The curve described by interconnecting these points is referred to as a generatrix. The plurality of locations (or points) (denoted by an “x” in FIG. 1) are points at which the electromagnetic near-field probe may be located in order to measure near-field values. The robotic arm on the multi-axis robot may transport the electromagnetic near-field probe to be located at those plurality of points, which are discrete locations along the generatrix. To generate the surface of revolution after the multi-axis robot has generated the generatrix, in one embodiment a rotational device rotates the AUT through 360 degrees. The near-field probe is stopped at each of a plurality of locations along the generatrix as the rotational device rotates the object through the 360 degrees, thereby generating the surface of revolution. In an embodiment, coordination of motion of the near-field probe along the generatrix and the axis of rotation may permit the generation of a spiral scan, as will be discussed below.

FIG. 1 depicts the generatrix and its associated parameters. In FIG. 1, a rotational device 100 has mounted on it an AUT 110. A robotic arm (not shown in FIG. 1), to which a near-field probe 170 is attached, generates a generatrix 150 at the above-mentioned plurality of locations, as the arm moves the probe 170 to those locations. In an embodiment, rotation of the rotational device 100 to rotate the AUT 110 in conjunction with movement of the robotic arm may add rotation to complete a surface of revolution. Electric field sample locations 160 are indicated with an “X”. In one aspect, the distribution of these discrete locations is based on the electrical size of the AUT. In an embodiment, motion of the near-field probe 170 along the generatrix 150 is such that the aperture 175 of the probe 170 remains tangential to the surface of revolution during data acquisition, though that particular probe orientation is not essential. According to embodiments, the probe orientation may be arbitrary, so long as the orientation enables data acquisition.

Motion of the probe 170 along the generatrix 150 may be performed in discrete steps during data acquisition (stop motion). In an embodiment, this data acquisition may be performed while the rotation stage 100 is moving. In an embodiment, two orthogonal linear polarization components are measured during acquisition, one circumferentially directed (aligned with the y-axis in FIG. 1) and a second that is tangential to the generatrix (parallel to the x/z plane in FIG. 1). However, this particular approach is not essential. Data acquisition can be carried out with any pair of polarizations. In an embodiment, polarizations in such a pair are orthogonal, but this may not be necessary.

The following parameters, denoted in FIG. 1, define the generatrix:
d_{W}: The total radius of the measurement surface.
d_{H}: The total height of the measurement surface.
r₁: The starting radius of curvature of the corner of the measurement surface.
r₂: The ending radius of curvature of the corner of the measurement surface.
H: The vertical straight section of the measurement surface.
W: The horizontal straight section of the measurement surface.
Θ: The angular extent of the lower curved corner of the measurement surface (0° Θ≥90°).
z₀: The height of the measurement surface above the coordinate system origin.

These parameters simplify definition of the measurement surface and enable adaptation of the surface for many different types of antennas and definition of the scanning surfaces as shown in Table 1 below. The table shows typical values, for non-limiting examples of scanning surfaces, that allow the user to define:
A plane polar scanning surface of diameter 2 W;
A capped cylindrical surface of diameter 2 W;
A hemispherical surface of radius r₁=r₂;
A partial oblate spheroid a minor axis r₁ and a major axis r₂;
A partial prolate spheroid with a major axis r₁ and a minor axis r₂.

TABLE 1

| Scanning Surface | d_{W} (m) | W (m) | d_{H} (m) | H (m) | r₁ (m) | r₂ (m) | Θ | z_{Θ} (m) |
|---|---|---|---|---|---|---|---|---|
| 1 m Radius plane- | 1 | 1 | 0 | 0 | 0 | 0 | 0° | Arbitrary |
| polar surface | | | | | | | | |
| 0.5 m Radius, | 0.5 | 0.5 | 1 | 1 | 0 | 0 | 0° | 1 |
| 1 m tall capped | | | | | | | | |
| cylindrical | | | | | | | | |
| surface | | | | | | | | |
| 0.5 m Radius | 0.5 | 0 | 0.5 | 0 | 0.5 | 0.5 | 0° | 0.5 |
| hemispherical | | | | | | | | |
| surface | | | | | | | | |
| 0.5 m Radius | 0.5 | 0 | 0.75 | 0 | 0.5 | 0.5 | 45° | 0.75 |
| partial spherical | | | | | | | | |
| surface | | | | | | | | |
| Partial oblate | 0.5 | 0 | 0.175 | 0 | 0.25 | 0.5 | 45° | 0.175 |
| spheroid | | | | | | | | |
| Partial prolate | 0.25 | 0 | 0.75 | 0 | 0.5 | 0.25 | 45° | 0.75 |
| spheroid | | | | | | | | |

As for the distance of the points in the generatrix from the AUT, in one embodiment the points generally track the contour of the shape of the AUT. The points may be closer to or farther away from the AUT, as necessary or appropriate. The closer the points are to the AUT, the more the generatrix may conform to the shape of the AUT. The surface of revolution around the AUT need not be conformal, but in an embodiment it is conformal.

In an embodiment, in order to effect the rotation, it is possible to have the AUT be stationary, and to rotate the robot (or the robot's arm) around the AUT, rather than rotating the AUT. It is relative motion between the AUT, on the one hand, and the electromagnetic near-field probe on the robot arm, on the other, that yields the generatrix and the resulting surface of revolution.

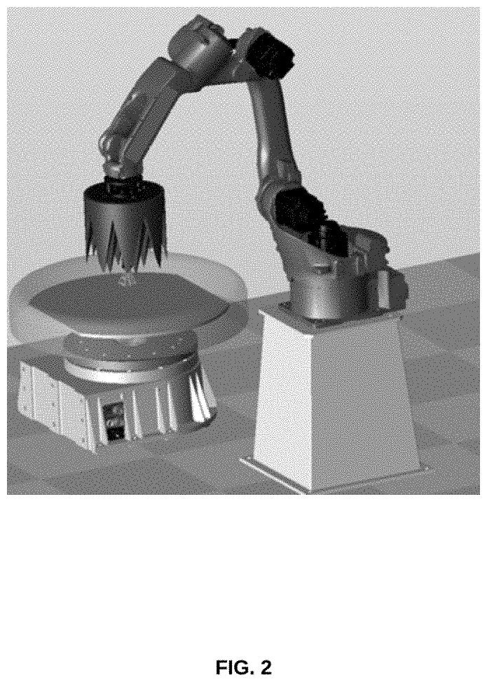

FIG. 2 shows the multi-axis robot with the electromagnetic near-field probe mounted at the end of the robot's arm. A rotational device has mounted on it a slotted waveguide array as the AUT. The combined motion of the robot and the rotational device define the shaded surface around the slotted waveguide array. That shaded surface may be referred to as a capped cylinder, meaning that in addition to the sides that the generatrix generates, there are points mapped above those sides. Another term for this capped cylinder shape is “pillbox”. In FIG. 2, the “pillbox” is fairly close to the flat antenna, and is somewhat conformal. As the rotational device rotates the slotted waveguide array, the generatrix that the robot generates goes around the slotted waveguide array, yielding the pillbox shape.

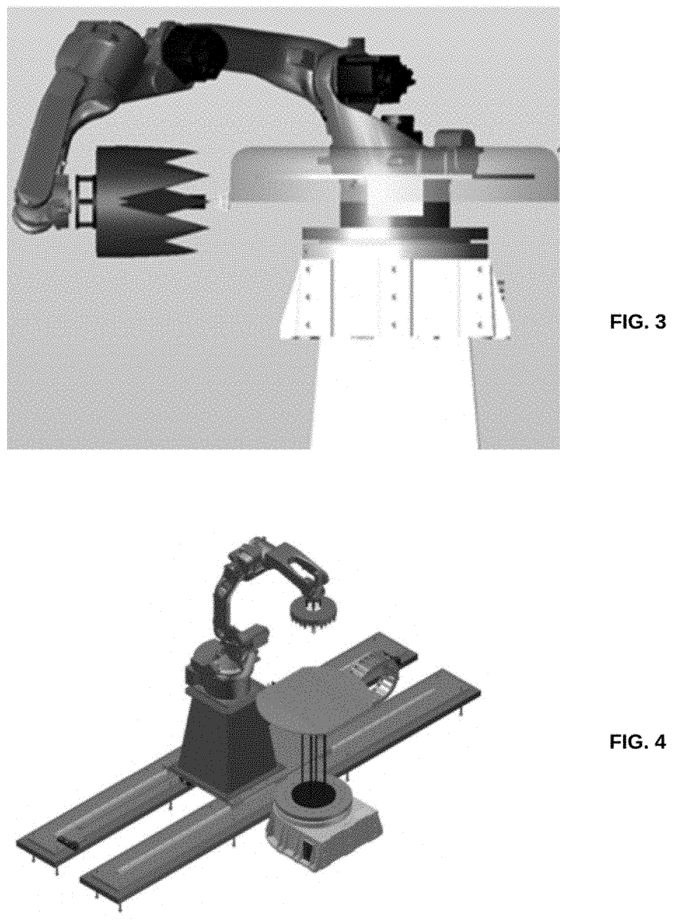

FIG. 3 shows a different view of the multi-axis robot, electromagnetic near-field probe, and rotational device of FIG. 2. In FIG. 3, the arm of the multi-axis robot is pointing the electromagnetic near-field probe at a different portion (edge) of the slotted waveguide array.

In one embodiment, the multi-axis robot shown in FIGS. 2-4 is a six-axis robot. With a rotational device rotating either the robot or the AUT about a single axis, the overall system would be a seven-axis system. FIG. 4 shows the multi-axis robot mounted on a translational device (though in other embodiments, the AUT could be mounted on the translational device). With a translational device, which can move either the robot or the AUT along an axis that is orthogonal to the axis of rotation of the rotational device, the overall system would be an eight-axis system. Generally, the additional axis would not be necessary to generate the surface of revolution described above. It is within the contemplation of the invention that there could be surfaces which translational movement could help to generate.

Also, while FIGS. 2-4 show the axis of rotation of the rotational device as perpendicular, the axis of rotation could be at another orientation if necessary or desired.

In systems such as the ones shown FIGS. 2-4, in an embodiment, the electromagnetic near-field probe is designed to have low gain and high polarization purity, but these characteristics are not essential. Such a probe may take different shapes, as a function of wavelength and other measurement factors known to ordinarily skilled artisans.

Using a rotationally symmetric parametric surface defined herein enables substantial customizability, and presents a user with a well characterized surface definition, thereby reducing risk of damage to the antenna under test.

For a canonical acquisition surface, for an AUT of 80 cm diameter, a plane-polar scanning surface of 1 m diameter will support a ±45° far-field viewing angle (assuming a 3X probe distance at X-band frequency), where X is wavelength. If this were to be increased to a ±85° viewing angle, a plane-polar scanning surface of 3 m diameter would be necessary. It would not be possible to achieve larger viewing angles.

For the same AUT, for a non-canonical acquisition surface, one way of overcoming angular limitations is as follows. If the robotic arm not only moves the probe along a straight line trajectory, but also turns the probe by 90°, thereby describing a capped cylinder, or a “pillbox,” it is possible to achieve a ±135° viewing angle for a cylinder diameter of 1 m and height of only 20 cm, resulting in a space-efficient test system.

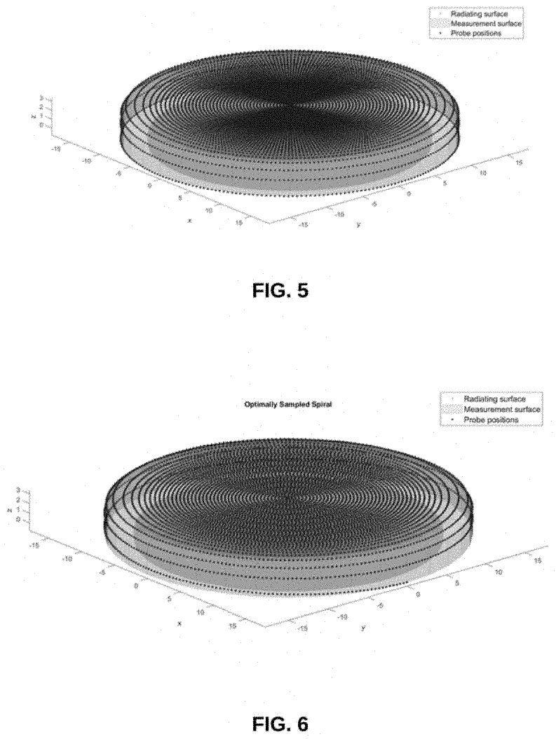

FIG. 5 shows sample points for a near-field (NF) pillbox measurement surface enclosing and measuring the slotted waveguide array. Systems according to FIGS. 2-4 may generate the measurement surface in FIG. 5. FIG. 5 shows an example of sampling along the generatrix.

FIG. 5 shows an example of scan lines around an axis of rotation using the points on the generatrix. In one embodiment, the FIGS. 2-4 systems carry out sampling in equal increments along the generatrix, and/or around the axis of rotation. In another embodiment, depending on the geometry of the AUT, sampling may occur in irregular increments along the generatrix, and/or around the axis of rotation, in order to appropriately capture the near-field radiation from the AUT.

FIG. 6 shows a different approach to generating the NF pillbox measurement surface. A comparison between FIG. 5 and FIG. 6 shows that the measurement points in FIG. 6 result from a spiral scan. In the approach in FIG. 6, a near-field probe moves continuously along a generatrix, and a surface of revolution results through relative movement between the AUT and the multi-axis robot. Systems according to FIGS. 2-4 may generate the FIG. 6 measurement surface that encloses the AUT.

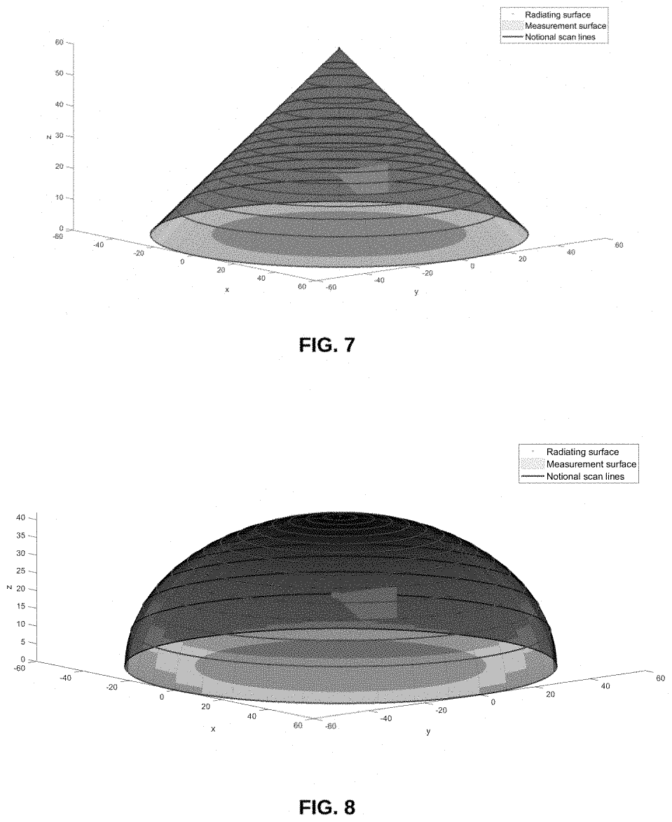

FIG. 7 shows sample points for an NF conical measurement surface measuring a horn antenna over a finite flat ground plane. Systems according to FIGS. 2-4 may generate the FIG. 7 measurement surface that encloses the AUT. FIG. 7 shows an example of scan lines around an axis of rotation for the generatrix. In one embodiment, the FIGS. 2-4 systems carry out sampling in equal increments along the generatrix, and/or around the axis of rotation. In another embodiment, depending on the geometry of the AUT, sampling may occur in irregular increments along the generatrix, and/or around the axis of rotation, in order to appropriately capture the near-field radiation from the AUT.

FIG. 8 shows sample points for an NF partial oblate spherical surface measuring a horn antenna over a finite flat ground plane. Systems according to FIGS. 2-4 may generate the FIG. 8 measurement surface that encloses the AUT. FIG. 8 shows an example of scan lines around an axis of rotation for the generatrix. In one embodiment, the FIGS. 2-4 systems carry out sampling in equal increments along the generatrix, and/or around the axis of rotation. In another embodiment, depending on the geometry of the AUT, sampling may occur in irregular increments along the generatrix, and/or around the axis of rotation, in order to appropriately capture the near-field radiation from the AUT.

Other examples of suitable surfaces of revolution which are attainable in accordance with aspects of the present invention include a closed coaxial cylinder and a partial sphere. Other surfaces of revolution are possible as a function of the shape of the antenna being measured. Application of embodiments of the invention to generate a sphere as a surface of revolution also is possible, it being noted that that particular surface of revolution has been generated using other, known techniques.

In an embodiment, the inventive near-field measurement approach relies on inverse equivalent source solvers for transformation of measured near-field data into a set of equivalent sources. These sources, acting as proxies to the original AUT, then can be used to calculate near and far-fields, enabling near-field antenna measurements to be made on non-canonical surfaces and/or with irregular sampling grids. A by-product of these inverse equivalent source solvers is that they allow a very flexible modeling of the AUT, which can, with the inclusion of a priori knowledge about the geometric extent of the AUT, provide “measured” currents on the antenna structure. Examples of such solvers may be found in the following: T. F. Eibert and C. H. Schmidt, “Multilevel Fast Multipole Accelerated Inverse Equivalent Current Method Employing Rao-Wilton-Glisson Discretization of Electric and Magnetic Surface Currents,” IEEE Transactions on Antennas and Propagation, vol. 57, pp. 1178-1185, 4 2009; C. H. Schmidt, M. M. Leibfritz and T. F. Eibert, “Fully Probe-corrected Near-field Far-field Transformation Employing Plane Wave Expansion and Diagonal Translation Operators,” IEEE Transactions on Antennas and Propagation, vol. 56, pp. 737-746, 3 2008.

An additional aspect of the non-canonical transformation techniques described herein is that, not only do these algorithms support irregular sampling on arbitrary measurement surfaces; but also they are commonly based on very flexible radiation models of the AUT. Since the AUT radiation is represented by equivalent sources, which exist on a surface enclosing the actual AUT, knowledge about the size and shape of the AUT can be considered in setting up the equivalent radiation model. These equivalent sources are based on the well-known surface equivalence theorem in electromagnetics.

The measurement sequence in this case requires a near-field measurement to be performed by moving a near-field probe over a surface described by the generatrix shown in FIG. 1. Through combined motion of the robotic arm and the rotary positioner, electric field values are acquired at discrete coordinates. FIG. 5, discussed above, shows a distribution of these sample points. In FIG. 5, each dot represents a grid point on the non-canonical measurement surface where two orthogonal electric field samples are acquired.

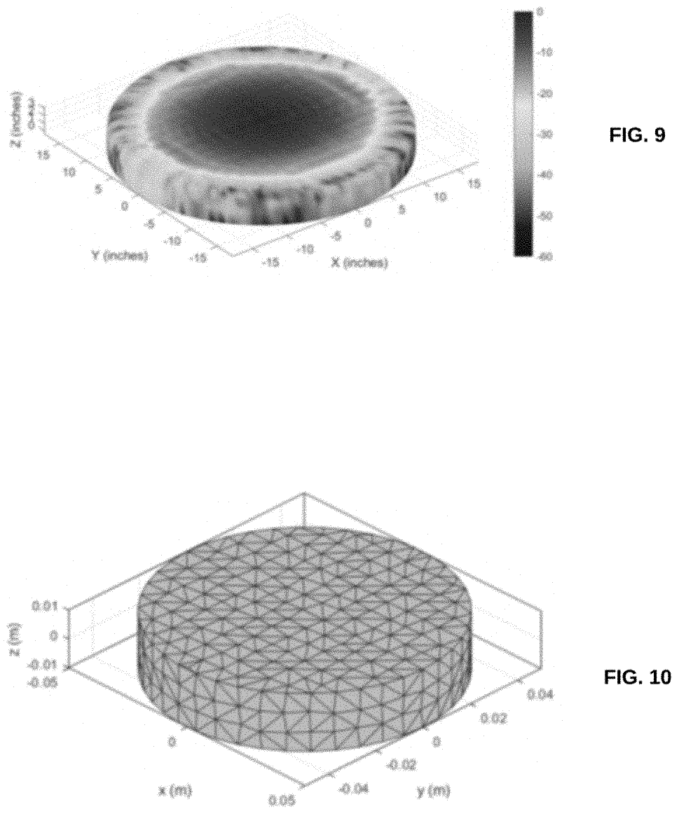

An illustration of the magnitude of the acquired electric field values measured at the points shown in FIG. 5 is shown as a false shaded image in FIG. 9, wherein it is possible to see the shape of the capped cylindrical surface.

Following this acquisition is selection of a surface enclosing the AUT. This enclosing surface may be termed an AUT bounding surface, in contrast to a measurement surface. This bounding surface is where the equivalent sources would be computed and from which all final near-field and far-field values are derived. In one aspect, using computational electromagnetics principles, this bounding surface is discretized, and aspects like solution convergence considered. FIG. 10 shows an example of such a discretized AUT bounding surface. In some aspects, the AUT bounding surface for a slotted waveguide such as the one depicted in FIG. 2 is cylindrical. For some test cases, discretization of the bounding surface may be difficult to discern. Accordingly, for ease of illustration, FIG. 10 shows a smaller discretized surface.

In one aspect, the bounding surface does not need to conform to the AUT surface, though it must enclose all parts of the AUT, and not extend beyond the measurement surface. In one aspect, the bounding surface also may be separated from the measurement surface by more than a few wavelengths to ensure that reactive coupling between the measured field samples and the equivalent currents can be neglected.

In one aspect, selection of the equivalent bounding surface to be conformal to the AUT surface can be advantageous for diagnostics purposes, provided that alignment of this bounding surface with respect to the actual AUT is done with care.

Once the equivalent source currents are resolved, there is a representation of the AUT that enables computation of all radiation parameters of interest, exterior to the AUT bounding surface. There is the resulting advantage of a test solution that can be tailored for the specific AUT (making for a more space efficient solution) and can obviate the need for precise mechanical near-field probe positioning, as may have been attempted in prior approaches, in exchange for knowing the precise near-field probe location.

In one example, a known AUT (a 30″ diameter slotted waveguide array as depicted in FIG. 2) was selected and tested using the inventive technique. For the spherical acquisition, the robotic arm was used as the e-axis and the rotary positioner was used as the ϕ-axis. Near-field to far-field processing was performed using a regular modal expansion technique.

The AUT also was measured using a capped cylinder measurement surface, sampling on a grid of points as depicted in FIG. 5. A thin cylindrical AUT bounding surface was defined, and equivalent surface currents solved for. Based on these, far-field radiation patterns were computed.

In one aspect, sampling along the generatrix can be done in a number of ways, as ordinarily skilled artisans will appreciate. Two such approaches, which here are exemplary and are not intended to be limiting, are as follows:

Optimal Sampling: In order to create valid far-field patterns from the near-field samples, the samples should be spaced close enough to capture the spatial bandwidth of the signal coming from the antenna. In order to capture that spatial bandwidth information optimally, one approach is to use the theory discussed in O. M. Bucci, G. Franceschetti, “On the spatial bandwidth of scattered fields”, IEEE Trans. Antennas Propagat., vol. AP-35, pp. 1445-1455, December 1987, Section IV. In this optimal acquisition approach, the spacing of sample points depends on the geometry of the antenna being tested. Other approaches to optimal sampling will be known to ordinarily skilled artisans.

Equal Increment Sampling: Another approach would be to take the samples in increments of no more than λ/2 along the measurement surface, where X denotes wavelength. As ordinarily skilled artisans will appreciate, there will be antenna configurations which will warrant this approach, particularly in view of the signals that a particular antenna generates. However, this approach will not necessarily be the most preferred in all circumstances. Optimal sampling, an example of which is discussed immediately above, may do a better job of accounting for the signals coming from the antenna.

Once probe positions along the generatrix have been defined, it is necessary to define how samples are to be collected along the axis of rotation (denoted as φ below). Two approaches, which here are exemplary and are not intended to be limiting, are as follows:

Optimal Sampling: Here also, it is possible to apply the theory in O. M. Bucci, G. Franceschetti, “On the spatial bandwidth of scattered fields”, IEEE Trans. Antennas Propagat., vol. AP-35, pp. 1445-1455, December 1987, Section IV. In this circumstance, the technique would be applied to finding optimal sample points along cp. Other approaches to optimal sampling will be known to ordinarily skilled artisans.

Equal Increment Sampling: It is possible to sample in equal increments along the φ-axis using standard spherical near-field theory as described, for example, in J. E. Hansen, ed., “Spherical near-field antenna measurements,” IEE Electromagnetic Waves Series, Peter Peregrinus, London, U K, 1998, Chapter 4. As ordinarily skilled artisans will appreciate, there will be antenna configurations which will warrant this approach, particularly in view of the signals that a particular antenna generates. However, this approach will not necessarily be the most preferred in all circumstances. Optimal sampling, an example of which is discussed immediately above, may do a better job of accounting for the signals coming from the antenna.

Spiral Sampling: As an alternative, it is possible to employ the process described in B. T. Walkenhorst, S. T. McBride, “Acquisition, reconstruction, and transformation of a spiral near-field scan”, AMTA Symposium, October 2017, Section 1, and F. D'Agostino, C. Gennarelli, G. Riccio, C. Savarese, “Theoretical foundations of near-field-far-field transformations with spiral scannings,” Progress in Electromagnetics Research (PIER), vol. 61, pp. 193-214, 2006, Section 2, to sample positions in a spiral with coordinated motion of the two axes (Θ and φ) controlling the probe position.

Sampling along the generatrix and rotation of the φ axis creates the closed surface, with measurements being taken at discrete positions as depicted in FIGS. 5 and 6.

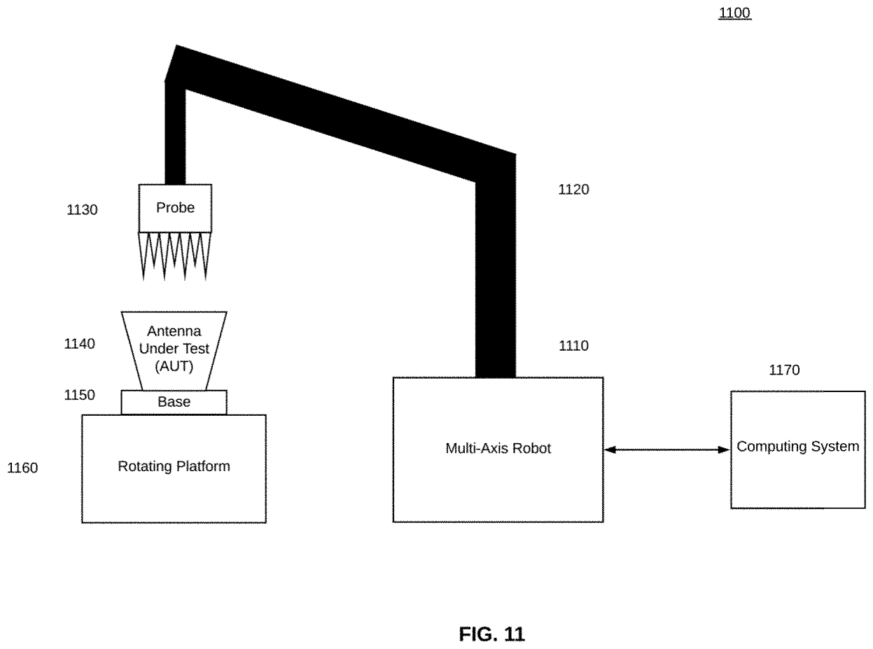

FIG. 11 is a high-level view of a testing system, in which a multi-axis robot 1110 has an arm 1120 on which is mounted a probe 1130. AUT 1140 is seated on a base 1150 which in turn is on a rotating platform 1160. Robot 1110 communicates with computing system 1170 to formulate different near-field measurement schemes. In one scheme, knowing the dimensions of the AUT 1140, relative movement between the base 1150 and the probe 1130 defines a generatrix which, when rotated through a full revolution, defines an arbitrary closed surface around AUT 1140. The relative movement may be achieved by rotating the base 1150 on the rotating platform 1160. Alternatively, the relative movement may be achieved by moving the arm 1120 and/or the robot 1120 around the AUT 1140.

While platform 1160 rotates in one embodiment, in another embodiment the platform 1160 may be stationary, and the arm 1120 and/or the robot 1110 can move all the way around the AUT 1140. Platform 1160 can move translationally, as FIG. 4 depicts.

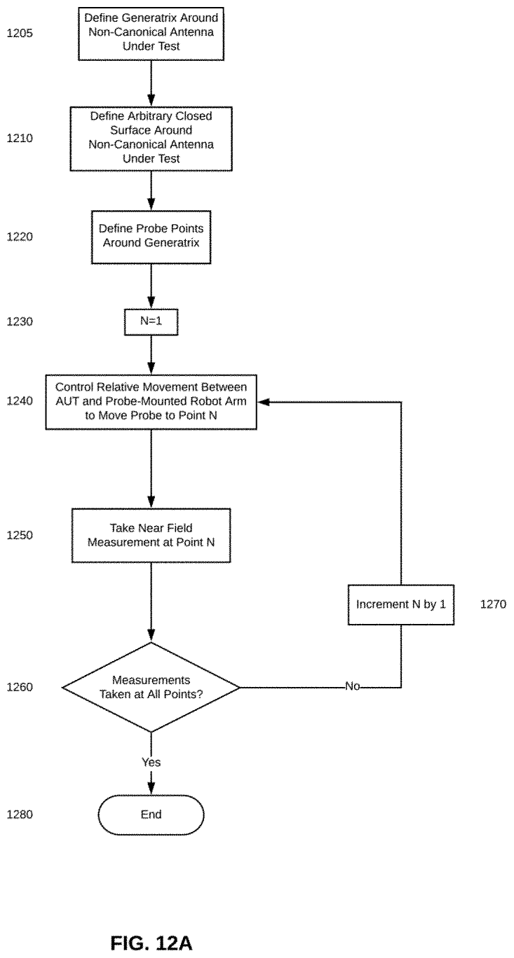

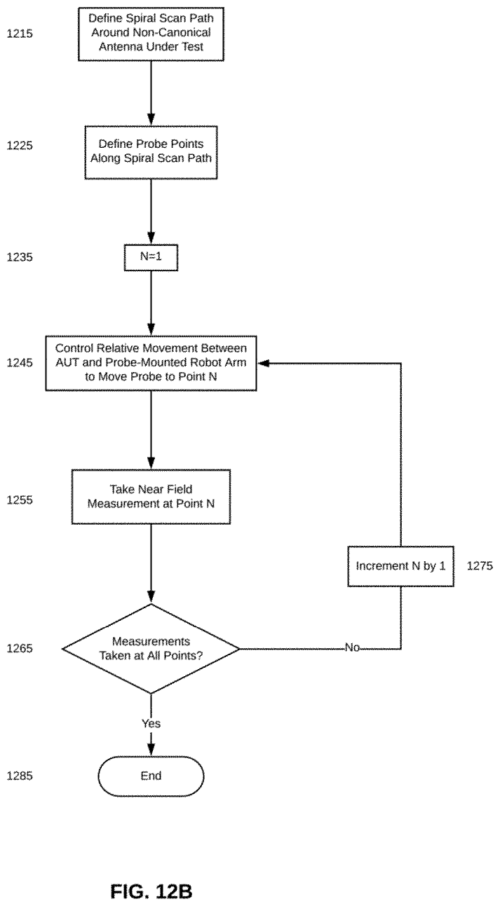

FIG. 12A is a flow chart depicting an exemplary sequence in which near-field measurements are taken based on a generatrix which the inventive system produces. In FIG. 12A, the computing system 1170 in FIG. 11 takes the dimensions of the AUT and defines an arbitrary closed surface, with an appropriate number of points along that arbitrary closed surface, at which the electromagnetic NF probe 1130, under appropriate motion either by the robot 1110, or the arm 1120, or the rotating platform 1160, or any combination of these three, can effect the appropriate relative movement between the AUT 1140 and the electromagnetic probe 1130 to get the probe 1130 to all of those points.

Looking at FIG. 12A, at 1205, the computing system 1170, in conjunction with the electromagnetic NF probe 1130, defines a generatrix for a non-canonical surface. At 1210, the computing system 1170, in conjunction with the electromagnetic NF probe 1130, defines a non-canonical arbitrary closed surface, using the generatrix of points which is rotated to form a non-canonical arbitrary closed surface in a single revolution. This non-canonical arbitrary closed surface encloses the AUT. At 1220, probe points are defined along that non-canonical arbitrary closed surface. At 1230, the first point to be probed is set (a value N being set to 1), and at 1240, relative movement among the AUT and the robot arm 1120 moves the probe to that first point. At 1250, a near field measurement is taken.

Next, the loop at 1260 and 1270 takes into account all of the remaining points at which values are to be taken. At 1260, if all of the points have not yet been probed, at 1270, N is incremented by 1, and flow returns to 1240, to move the probe to the next point.

As mentioned earlier, the approach set forth in the flow chart of FIG. 12A may be used for spiral scans. As another way of performing a spiral scan, FIG. 12B is a flow chart depicting an alternative process to that in FIG. 12A. In FIG. 12B, a spiral scan is used to obtain samples. The computing system 1170 in FIG. 11 takes the dimensions of the AUT and defines an arbitrary closed surface, with an appropriate number of points along that arbitrary closed surface, at which the electromagnetic NF probe 1130, under appropriate motion either by the robot 1110, or the arm 1120, or the rotating platform 1160, or any combination of these three, can effect the appropriate relative movement between the AUT 1140 and the electromagnetic probe 1130 to get the probe 1130 to all of those points.

Looking at FIG. 12B, at 1215, the computing system 1170, in conjunction with the electromagnetic NF probe 1130, defines a non-canonical arbitrary closed surface, and a spiral scan path along that surface, around an AUT. At 1225, probe points are defined along that spiral scan path. At 1235, the first point to be probed is set (a value N being set to 1), and at 1245, relative movement among the AUT and the robot arm 1120 moves the probe to that first point. At 1255, a near field measurement is taken.

Next, the loop at 1265 and 1275 takes into account all of the remaining points at which values are to be taken. At 1265, if all of the points have not yet been probed, at 1275, N is incremented by 1, and flow returns to 1245, to move the probe to the next point.

In FIGS. 12A and 12B, the references to a value or counter N, and to incrementing that value or counter, are merely illustrative. Sequencing of points to be probed along the arbitrary closed surface can be handled in many different ways, as ordinarily skilled artisans will appreciate.

The following articles are incorporated by reference in their entirety herein as though they were set forth verbatim in this application:
O. M. Bucci, G. Franceschetti, “On the spatial bandwidth of scattered fields”, IEEE Trans. Antennas Propagat., vol. AP-35, pp. 1445-1455, December 1987.
J. E. Hansen, ed., “Spherical near-field antenna measurements,” IEE Electromagnetic Waves Series, Peter Peregrinus, London, U K, 1998.
B. T. Walkenhorst, S. T. McBride, “Acquisition, reconstruction, and transformation of a spiral near-field scan”, AMTA Symposium, October 2017.
F. D'Agostino, C. Gennarelli, G. Riccio, C. Savarese, “Theoretical foundations of near-field-far-field transformations with spiral scannings,” Progress in Electromagnetics Research (PIER), vol. 61, pp. 193-214, 2006.
T. F. Eibert and C. H. Schmidt, “Multilevel Fast Multipole Accelerated Inverse Equivalent Current Method Employing Rao-Wilton-Glisson Discretization of Electric and Magnetic Surface Currents,” IEEE Transactions on Antennas and Propagation, vol. 57, pp. 1178-1185, 4 2009.
C. H. Schmidt, M. M. Leibfritz and T. F. Eibert, “Fully Probe-corrected Near-field Far-field Transformation Employing Plane Wave Expansion and Diagonal Translation Operators,” IEEE Transactions on Antennas and Propagation, vol. 56, pp. 737-746, 3 2008.

While the foregoing description provides details of some exemplary embodiments, various modifications within the scope and spirit will be apparent to ordinarily skilled artisans. Accordingly, the invention should be considered as limited only by the scope of the following claims.

What is being claimed is:

1. A near-field (NF) antenna test system to acquire electromagnetic field samples at a plurality of locations along an arbitrary closed surface enclosing an antenna under test (AUT), the system comprising:
An AUT platform supporting the AUT;
a multi-axis robot;
an electromagnetic NF probe, mounted on the multi-axis robot; and
a computing system to identify a plurality of locations to define the arbitrary closed surface based on dimensions of the AUT, the electromagnetic NF probe acquiring the electromagnetic field samples at the plurality of points under control of the computing system through relative movement between the electromagnetic NF probe and the platform.

2. A system as claimed in claim 1, wherein the computing system defines a generatrix, wherein the arbitrary closed surface is a surface of revolution which is generated by rotating the generatrix through a full revolution, around a single axis, of relative movement between the electromagnetic NF probe and the AUT.

3. A system as claimed in claim 2, wherein the arbitrary closed surface is generated by rotating the AUT about a single axis, or by rotating the electromagnetic NF probe around the AUT, through a full revolution.

4. A system as claimed in claim 1, wherein the arbitrary closed surface is generated by the computing system controlling the position of the electromagnetic NF probe and/or the AUT platform to perform a spiral scan around the arbitrary closed surface, the plurality of locations being on a path of the spiral scan.

5. A system as claimed in claim 4, wherein the spiral scan is performed by rotating the AUT about a single axis, or by rotating the electromagnetic NF probe around the AUT.

6. A system as claimed in claim 1, wherein the arbitrary closed surface is conformal to the AUT.

7. A system as claimed in claim 1, wherein the arbitrary closed surface is not conformal to the AUT.

8. A system as claimed in claim 1, further comprising a rotational device on which the AUT platform is mounted, the rotational device configured to rotate around the single axis.

9. A system as claimed in claim 1, further comprising a rotational device on which the multi-axis robot is mounted, the rotational device configured to rotate around the single axis.

10. A system as claimed in claim 1, further comprising a translational device to translate one of the AUT platform or the multi-axis robot.

11. A system as claimed in claim 1, wherein the multi-axis robot is a six-axis robot.

12. A system as claimed in claim 10, wherein the multi-axis robot is a six-axis robot, such that the system is an eight-axis system.

13. A computer-implemented method of acquiring electromagnetic field samples at a plurality of locations along an arbitrary closed surface enclosing an antenna under test (AUT), the method comprising:
using a computing system, identifying a plurality of locations based on dimensions of the AUT;
generating the arbitrary closed surface using the plurality of locations; and
using an electromagnetic NF probe, acquiring the electromagnetic field samples at the plurality of points under control of the computing system through relative movement between the electromagnetic NF probe and a platform on which the AUT is mounted.

14. A method as claimed in claim 13, wherein the identifying comprises defining a generatrix, wherein the arbitrary closed surface is a surface of revolution which is generated by rotating the generatrix through a full revolution, around a single axis, of relative movement between the electromagnetic NF probe and the AUT, the computing system to control the position of the electromagnetic NF probe to acquire the electromagnetic field samples.

15. A method as claimed in claim 14, wherein the generating comprises rotating the AUT about a single axis, or by rotating the electromagnetic NF probe around the AUT, through a full revolution.

16. A method as claimed in claim 13, wherein the generating comprises controlling movement of the electromagnetic NF probe and/or the platform to perform a spiral scan around an arbitrary closed surface, the plurality of locations being on a path of the spiral scan.

17. A method as claimed in claim 16, wherein performing the spiral scan comprises rotating the AUT about a single axis, or by rotating the electromagnetic NF probe around the AUT.

18. A method as claimed in claim 13, wherein the arbitrary closed surface is conformal to the AUT.

19. A method as claimed in claim 13, wherein the arbitrary closed surface is not conformal to the AUT.

20. A method as claimed in claim 13, further comprising translating one of the AUT and the electromagnetic NF probe to identify the plurality of locations.
